(19) United States
(12) Patent Application Publication
(10) Pub. No.: US 2007/0128796 A1
(43) Pub. Date: Jun. 7, 2007

(54) METHOD FOR MANUFACTURING NON-VOLATILE MEMORY

(76) Inventor: Chih-Hsun Chu, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/307,426

(22) Filed: Feb. 7, 2006

(30) Foreign Application Priority Data
Dec. 5, 2005 (TW) 94142751

(51) Int. Cl. H01L 21/336

(52) U.S. Cl. 438/257; 438/264; 438/266; 977/840

(57) ABSTRACT

A method for manufacturing a non-volatile memory is provided. First, a tunneling dielectric layer is formed over a substrate. A plurality of silicon nanocrystals is formed on the tunneling dielectric layer. A silicide process is performed on the silicon nanocrystals to form a plurality of salicide nanocrystals. A dielectric layer and a conductive layer are sequentially formed on the substrate to cover the salicide nanocrystals and the tunneling dielectric layer. The conductive layer, the dielectric layer, the salicide nanocrystals and the tunneling dielectric layer are patterned to form a gate structure. A source/drain region is formed in the substrate on the respective sides of the gate structure.

### CROSS-REFERENCE TO RELATED APPLICATION

This application claims the priority benefit of Taiwan application Ser. No. 94142751, filed on Dec. 05, 2005. All disclosure of the Taiwan application is incorporated herein by reference.

### BACKGROUND OF THE INVENTION

1. Field of the Invention

The present invention relates to a method for manufacturing a memory. More particularly, the present invention relates to a method for manufacturing a non-volatile memory.

2. Description of the Related Art

Memory is a semiconductor device specially designed for the storage of programs or data. Since non-volatile memory can retain stored data even after the power to the device is cut off, it has become an indispensable data storage element in many types of electronic products for holding normal start-up programs. In fact, it has become one of the most widely adopted memory devices in personal computer and electronic equipment.

A typical non-volatile memory has floating gates and control gates fabricated using doped polysilicon. When data are written into the memory, the electric charges injected into the floating gate will be evenly distributed throughout the entire polysilicon floating gate. However, if the tunneling oxide layer underneath the polysilicon floating gate has some defects, the defects will provide a pathway for the stored electrical charges to leak away, thereby affecting the reliability of the device. Obviously, aside from having a leakage current problem, the conventional non-volatile memory can hardly integrate with a typical complementary metal-oxide-semiconductor (CMOS) circuit process at the same time.

To resolve the current leakage problem in a non-volatile memory, a silicon-silicon oxide-silicon nitride-silicon oxide-silicon (SONOS) memory has been developed. The SONOS memory uses a charge-trapping layer instead of the polysilicon floating gate used in the conventional memory. The charge-trapping layer is fabricated using silicon nitride. Due to the charge-trapping property of silicon nitride, the electric charges injected into the charge-trapping layer will not be evenly distributed over the entire charge-trapping layer. Instead, the electric charges are collected in localized region within the charge-trapping layer. Although the charge-trapping layer can reduce the sensitivity to defects in the tunneling oxide layer compared with the polysilicon floating gate in the conventional memory so that comparatively less chances of current leakage occur, some of the regions with trapped electric charges are very close to the interface between the charge-trapping layer and the tunneling oxide layer. As a result, aforesaid charge-trapping layer still has difficulties restraining the outflow of current. In other words, the device leakage problem is only partially resolved.

At present, an innovative non-volatile memory device structure, namely, a nanocrystal non-volatile memory device that utilizes semiconductor nanocrystals instead of the polysilicon floating gate in a conventional memory to store electric charges, has been developed. In U.S. Patent publication 2005/0059213A1, a nanocluster semiconductor device has been disclosed. In the disclosed manufacturing process for the semiconductor device, an oxidation barrier layer is formed on the nanocluster. However, due to coulomb blockade, aforesaid nanocluster can only store a single electric charge at a time. As a result, a smaller threshold voltage window is obtained.

### SUMMARY OF THE INVENTION

Accordingly, at least one objective of the present invention is to provide a method for manufacturing a non-volatile memory such that the possibility of current leakage problem may be substantially reduced and the reliability of the device can be effectively promoted.

At least another objective of the present invention is to provide a method for manufacturing a non-volatile memory that can be integrated with the processes for forming the memory cell region and the peripheral circuit region and avoid any adverse effect on nanocrystals by subsequent processes.

To achieve these and other advantages and in accordance with the purpose of the invention, as embodied and broadly described herein, the invention provides a method for manufacturing a non-volatile memory. First, a tunneling dielectric layer is formed over a substrate. Then, a plurality of silicon nanocrystals is formed on the tunneling dielectric layer. Thereafter, a silicide process is performed on the silicon nanocrystals to form a plurality of salicide nanocrystals. After that, a dielectric layer and a conductive layer are sequentially formed on the substrate to cover the salicide nanocrystals and the tunneling dielectric layer. The conductive layer, the dielectric layer, the salicide nanocrystals and the tunneling dielectric layer are patterned to form a gate structure. Then, a source/drain region is formed in the substrate on the respective sides of the gate structure.

According to the embodiment of the present invention, the aforementioned silicide process includes, for example, forming a metallic layer over the substrate to cover the silicon nanocrystals and the tunneling dielectric layer. Then, a first rapid thermal annealing operation is performed so that the material in the metallic layer reacts with the silicon nanocrystals to form a plurality of salicide nanocrystals. Thereafter, the unreacted metallic layer is removed. In one embodiment, after removing the unreacted metallic layer, a second rapid annealing operation is performed, for example.

According to the embodiment of the present invention, the method of removing the residual metallic layer includes performing an etching operation, for example.

According to the embodiment of the present invention, the aforementioned metallic layer comprises a refractory metal, for example. The refractory metal is selected from a group consisting of titanium, tungsten, platinum, cobalt and nickel.

According to the embodiment of the present invention, the method of forming the silicon nanocrystals includes performing a chemical vapor deposition process, for example.

According to the embodiment of the present invention, the aforementioned conductive layer comprises doped polysilicon, for example.

The present invention also provides an alternative method for manufacturing a non-volatile memory. First, a substrate is provided. The substrate has a memory cell region and a peripheral circuit region. Then, a tunneling dielectric layer is formed over a substrate. Then, a plurality of silicon nanocrystals is formed on the tunneling dielectric layer. Thereafter, a silicide process is performed on the silicon nanocrystals to form a plurality of salicide nanocrystals. After that, a dielectric layer is formed over the substrate to cover the salicide nanocrystals and the tunneling dielectric layer. Next, the dielectric layer, the salicide nanocrystals and the tunneling dielectric layer within the peripheral circuit region are removed. A gate oxide layer is formed over the dielectric layer in the memory cell region and the substrate in the peripheral circuit region. A conductive layer is formed over the gate oxide layer. Thereafter, the conductive layer, the gate oxide layer, the dielectric layer, the salicide nanocrystals and the tunneling dielectric layer are patterned until the substrate surface is exposed. Hence, a first gate structure is formed in the memory cell region and a second gate structure is formed in the peripheral circuit region. After that, a first source/drain region is formed in the substrate on the respective sides of the first gate structure, and a second source/drain region is formed in the substrate on the respective sides of the second gate structures.

According to the embodiment of the present invention, the aforementioned silicide process includes, for example, forming a metallic layer over the substrate to cover the silicon nanocrystals and the tunneling dielectric layer. Then, a first rapid thermal annealing operation is performed so that the material in the metallic layer reacts with the silicon nanocrystals to form a plurality of salicide nanocrystals. Thereafter, the unreacted metallic layer is removed. In one embodiment, after removing the unreacted metallic layer, a second rapid annealing operation is performed, for example.

According to the embodiment of the present invention, the method of removing the residual metallic layer includes performing an etching operation, for example.

According to the embodiment of the present invention, the aforementioned metallic layer comprises a refractory metal, for example. The refractory metal is selected from a group consisting of titanium, tungsten, platinum, cobalt and nickel.

According to the embodiment of the present invention, the method of forming the silicon nanocrystals includes performing a chemical vapor deposition process, for example.

According to the embodiment of the present invention, the method of forming the aforementioned gate oxide layer includes performing a thermal oxidation process, for example.

According to the embodiment of the present invention, the method of removing the dielectric layer, the salicide nanocrystals and the tunneling dielectric layer in the peripheral circuit region includes forming a patterned photoresist layer over the dielectric layer in the memory cell region and etching the dielectric layer, the salicide nanocrystals and the tunneling dielectric layer in the peripheral circuit layer using the patterned photoresist layer as an etching mask.

According to the embodiment of the present invention, the aforementioned dielectric layer compriese silicon nitride, for example.

According to the embodiment of the present invention, the aforementioned conductive layer comprises doped polysilicon, for example.

In the present invention, a silicide process is performed to produce a layer of salicide nanocrystals that serves as a charge storage units. Hence, the present invention can have a greater threshold voltage window compared to the conventional semiconductor nanocrystal layer. Furthermore, because the charges are stored within the salicide nanocrystals, any defects in the tunneling dielectric layer will only lead to the loss of electric charges in the salicide nanocrystals situated close to the defects. The electric charges in other portion still remain trapped by the salicide nanocrystals. In other words, the reliability of the device is improved. Moreover, the manufacturing method in the present invention can be integrated with the processes of fabricating non-volatile memory in the memory cell region and the peripheral circuit region. As a result, the manufacturing operation can be simplified, the level of integration of the memory device can be increased and the production cost can be reduced. In addition, the present invention also includes forming a dielectric layer over the salicide nanocrystals to protect the salicide nanocrystals during the subsequent processes (such as an oxidation process). Ultimately, the reliability and performance of the device can be effectively promoted.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1F are schematic cross-sectional views showing the steps for producing a non-volatile memory according to one embodiment of the present invention.

FIGS. 2A through 2H are schematic cross-sectional views showing the steps for producing a non-volatile memory according to another embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

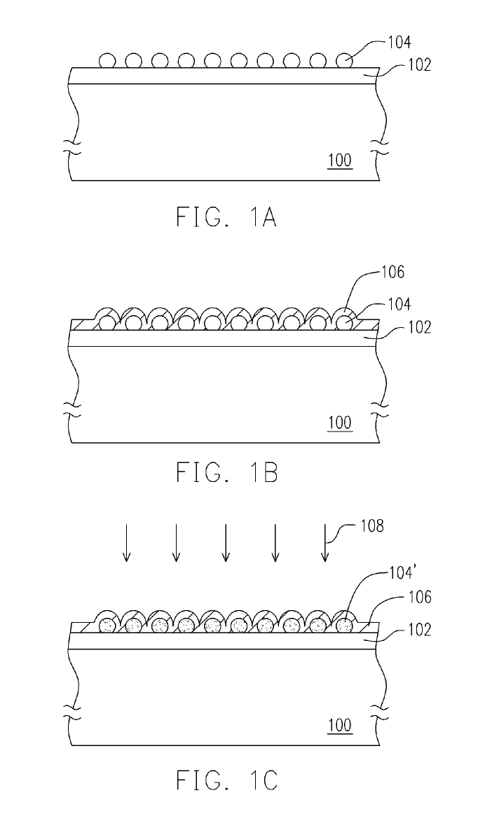

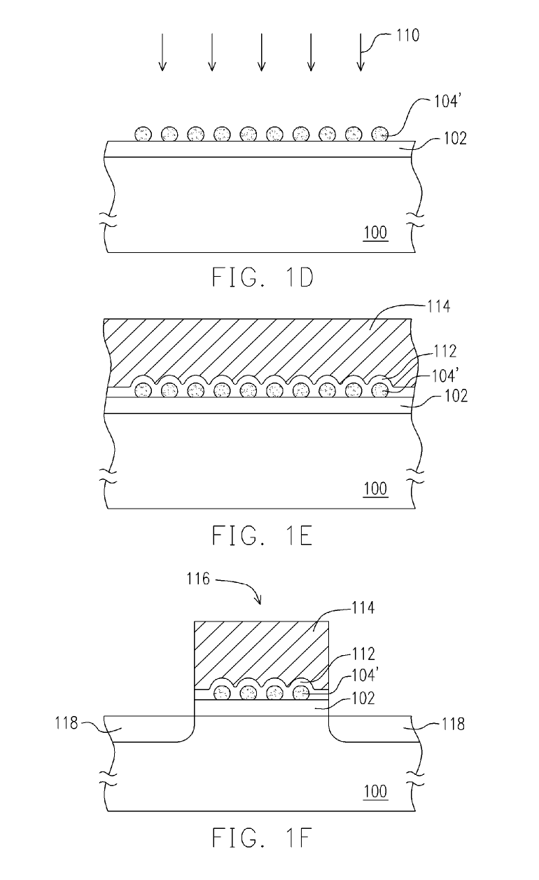

FIGS. 1A through 1F are schematic cross-sectional views showing the steps for producing a non-volatile memory according to one embodiment of the present invention. First, as shown in FIG. 1A, a substrate 100 is provided. The substrate 100 is a silicon substrate, for example. Then, a tunneling dielectric layer 102 is formed on the substrate 100. The tunneling dielectric layer 102 is a silicon oxide layer formed, for example, by performing a thermal oxidation process. Obviously, the tunneling dielectric layer 102 may also be fabricated by using some other suitable methods. Thereafter, a plurality of silicon nanocrystals 104 is formed on the tunneling dielectric layer 102. The silicon nanocrystals 104 comprises silicon and may be formed by performing a chemical vapor deposition process, for example. More specifically, the method of forming the silicon nanocrystals includes performing a chemical vapor deposition process to initiate crystal growth on the tunneling dielectric layer 102.

Then, a silicide process is performed to transform the silicon nanocrystals 104 into salicide nanocrystals 104′ that serves as charge storage units. The aforementioned silicide process, as shown in FIG. 1B, includes forming a metallic layer 106 over the substrate 100 to cover the silicon nanocrystals 104 and the tunneling dielectric layer 102. The metallic layer 106 comprises a refractory metal and the refractory metal is selected from a group consisting of titanium, tungsten, platinum, cobalt and nickel, for example. Furthermore, the method of forming the metallic layer 106 includes performing a sputtering deposition process, for example.

As shown in FIG. 1C, after forming the metallic layer 106, a first rapid thermal annealing (RTA) process 108 is carried out so that the metallic layer 106 reacts with the silicon nanocrystals 104 to form the salicide nanocrystals 104′.

As shown in FIG. 1D, the unreacted metallic layer 106 is removed. The method of removing the unreacted metallic layer 106 includes performing an etching operation, for example, a wet etching operation. In one embodiment, after removing the unreacted metallic material layer 106, a second rapid thermal annealing (RTA) process 110 is carried out with the reaction temperature higher than the first RTA process so that the salicide nanocrystals 104′ are transformed into a state having a lower resistance. Obviously, the reaction temperature, the reaction time and other processing conditions of the first rapid thermal annealing process 108 and the second rapid thermal annealing process 110 may differ according to the material constituting the metallic layer.

It should be noted that the silicide process is used in the present invention to form a plurality of salicide nanocrystals 104′ and the electric charges are stored in the independent salicide nanocrystals 104′. Furthermore, the conventional semiconductor nanocrystals can only store a single electric charge at a time due to the coulomb blockade effect so that the threshold voltage window is relatively small. The salicide nanocrystals in the present invention differ from the conventional semiconductor nanocrystals in that it can store a plurality of electric charges. Therefore, the threshold voltage window and the operating speed of the device are both increased.

As shown in FIG. 1E, a dielectric layer 112 is formed over the substrate 100 to cover the salicide nanocrystals 104′ and the tunneling dielectric layer 102. The dielectric layer 112 comprises silicon nitride and formed by performing a chemical vapor deposition process, for example. Obviously, the tunneling dielectric layer 102 may be fabricated using some other suitable methods. After that, a conductive layer 114 is formed over the dielectric layer 112. The conductive layer 114 comprises doped polysilicon, for example. The method of forming the conductive layer 114 includes performing a chemical vapor deposition process to form an undoped polysilicon layer (not shown) and performing an ion implantation thereafter. However, the method of forming the conductive layer 114 may include performing a chemical vapor deposition with in-situ reaction with the dopants through the passage of dopant-containing reactive gas.

As shown in FIG. 1F, the conductive layer 114, the dielectric layer 112, the salicide nanocrystals 104′ and the tunneling dielectric layer 102 are patterned to form a gate structure 116. Then, a source/drain region 118 is formed in the substrate 100 on the respective sides of the gate structure 116. The source/drain regions 118 are formed, for example, by performing ion implantation process. Thereafter, the conventional processes are carried out to complete the fabrication of the non-volatile memory. Since these processes are familiar to those skilled in this area, a detailed description thereof is omitted.

The present invention uses the salicide nanocrystals 104′ as storage units so that electric charges are stored within the salicide nanocrystals 104′. Thus, when the tunneling dielectric layer has some defects, only the electric charges in the salicide nanocrystals close to the defects will be lost through a leak. The electric charges within the salicide nanocrystals located in the other portions will be retained so that overall reliability of the device can be improved. Furthermore, the damage in a local area of the floating gate will only affect a small portion of the salicide nanocrystals 104′. Therefore, overall charge storage capacity or charge delivery property of the salicide nanocrystals 104′ will be negligibly affected.

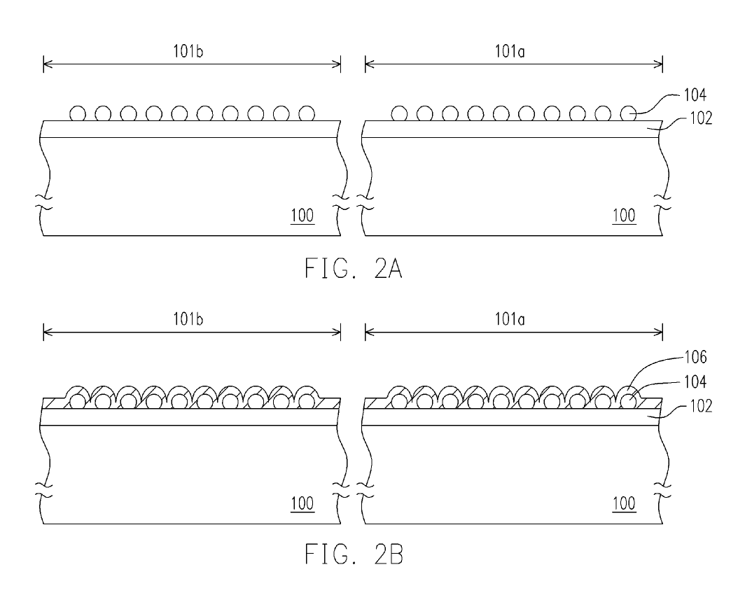

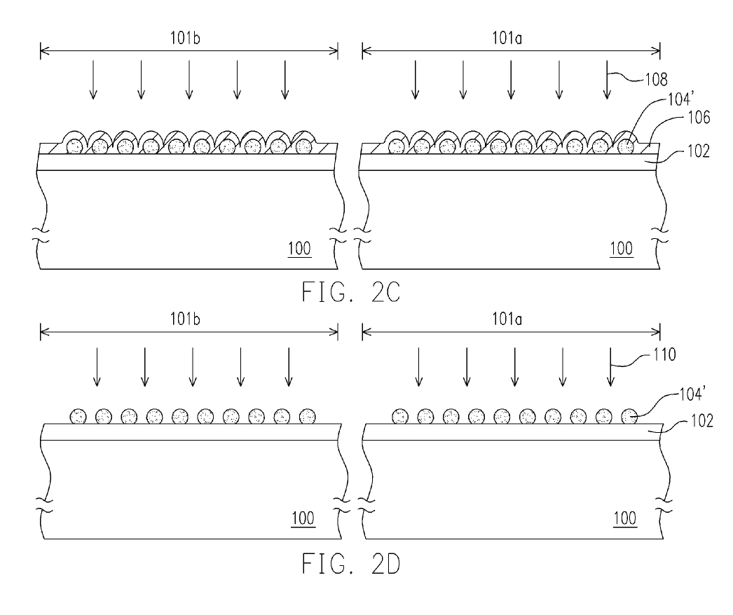

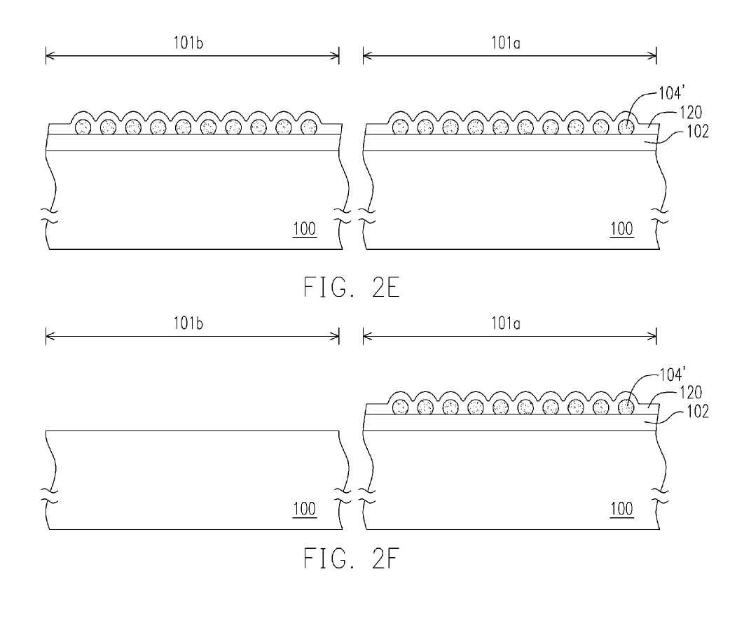

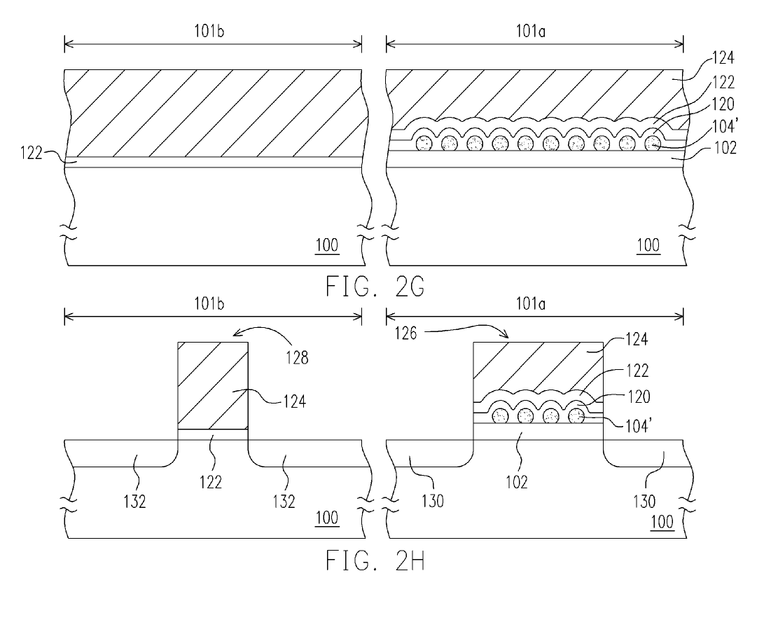

In addition, the method for manufacturing a non-volatile memory according to the present invention may also be integrated with the process of fabricating a peripheral circuit region so that a non-volatile memory that combines a memory cell region and a peripheral circuit region is easily formed on the same wafer. FIGS. 2A through 2H are schematic cross-sectional views showing the steps for producing a non-volatile memory according to another embodiment of the present invention. The processes from FIGS. 2A through to 2D are identical to the ones from FIGS. 1A through to 1D. Moreover, elements in FIGS. 2A through 2D identical to the elements in FIGS. 1A through 1D are labeled identically so that a formal description of those elements is omitted.

First, as shown in FIG. 2A, a substrate 100 is provided. The substrate 100 has a memory cell region 101a and a peripheral circuit region 101b. Then, a tunneling dielectric layer 102 is formed over the substrate 100. After that, a plurality of silicon nanocrystals 104 is formed on the tunneling dielectric layer 102.

Thereafter, a silicide process is carried out to convert the silicon nanocrystals 104 into a layer of salicide nanocrystals 104′ that serve as a floating gate. The aforementioned silicide process includes forming a metallic layer 106 over the substrate 100 to cover the silicon nanocrystals and the tunneling dielectric layer 102 as shown in FIG. 2B.

Then, as shown in FIG. 2C, a first rapid thermal annealing process 108 is performed so that the metallic layer 106 reacts with the silicon nanocrystals 104 to form a layer of salicide nanocrystals 104′.

Thereafter, as shown in FIG. 2D, the unreacted metallic layer 106 is removed. In one embodiment, after removing the unreacted metallic layer 106, further includes performing a second rapid thermal annealing process 110.

As shown in FIG. 2E, a dielectric layer 120 is formed over the substrate 100 to cover the salicide nanocrystals 104′ and the tunneling dielectric layer 102. The dielectric layer 120 comprises silicon nitride, for example. The method of forming the dielectric layer 120 includes performing a chemical vapor deposition process, for example. Obviously, the dielectric layer 120 may also be fabricated using other suitable methods. The dielectric layer 120 is set up as a barrier to prevent subsequent oxidation processes from affecting the salicide nanocrystals. With the barrier dielectric layer formed over the salicide nanocrystals, the salicide nanocrystals are protected against any adverse effect resulting from subsequent oxidation processes. Thus, the embodiment is safeguarded against a possible drop in reliability and performance of the device through oxidation.

As shown in FIG. 2F, the dielectric layer 120, the salicide nanocrystals 104′ and the tunneling dielectric layer 102 in the peripheral circuit region 101b are removed. The method includes forming a patterned photoresist layer (not shown) over the dielectric layer 120 in the memory cell region 101a. Then, using the patterned photoresist layer as an etching mask, the dielectric layer 120, the salicide nanocrystals 104′ and the tunneling dielectric layer 102 in the peripheral circuit region 101b are etched.

As shown in FIG. 2G, a gate oxide layer 122 is formed over the dielectric layer 120 in the memory cell region 101a and the substrate 100 in the peripheral circuit region 101b. The gate oxide layer 122 is a silicon oxide layer formed, for example, by performing a thermal oxidation process. Then, a conductive layer 124 is formed over the gate oxide layer 122. The conductive layer 124 can be fabricated using a material and a method identical to the conductive layer 114 in FIG. 1E so that a detailed description is not repeated here. In particular, because a dielectric layer 120 has already formed over the salicide nanocrystals 104′, the salicide nanocrystals 104′ will not be oxidized and hence its reliability will not be compromised in the process of forming the gate oxide layer 122.

As shown in FIG. 2H, the conductive layer 124, the gate oxide layer 122, the dielectric layer 120, the layer of salicide nanocrystal 104′ and the tunneling dielectric layer 102 are patterned until the surface of the substrate 100 is exposed. As a result, a gate structure 126 is formed in the memory cell region 101a and another gate structure 128 is formed in the peripheral circuit region 101b. Thereafter, a source/drain region 130 is formed in the substrate 100 on the respective sides of the gate structure 126. Similarly, a source/drain region 132 is formed in the substrate 100 on the respective sides of the gate structure 128. The method of forming the source/drain regions 130 and 132 includes performing a doping process, for example.

Thereafter, other related processes for fabricating the non-volatile memory are similarly carried out. Since these processes should be familiar to those skilled in the art, a detailed description thereof is omitted.

In summary, the present invention has at least the following advantages:

1. The present invention uses a layer of salicide nanocrystals as a charge storage unit. Thus, when the tunneling dielectric layer has some defects, only the electric charges in the salicide nanocrystals located close to the defects will be lost. The electric charges in the other portion of the salicide nanocrystals will be retained. As a result, the non-volatile memory can have a better reliability.

2. The salicide nanocrystals can store a large number of electric charges so that the threshold voltage window and the operating speed of the device can be increased.

3. The method in the present invention can be integrated with the fabrication of the memory cell region and the peripheral circuit region of a non-volatile memory. Ultimately, the processing steps are simplified and the level of integration of the memory device is increased while the production cost is reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for manufacturing a non-volatile memory, comprising the steps of:
forming a tunneling dielectric layer over a substrate;
forming a plurality of silicon nanocrystals on the tunneling dielectric layer;
performing a silicide process to transform the silicon nanocrystals into a plurality of salicide nanocrystals;
sequentially forming a dielectric layer and a conductive layer over the substrate to cover the salicide nanocrystals and the tunneling dielectric layer;
patterning the conductive layer, the dielectric layer, the layer of salicide nanocrystals and the tunneling dielectric layer to form a gate structure; and
forming a source/drain region in the substrate on the respective sides of the gate structure.

2. The method of claim 1, wherein the silicide process comprises:
forming a metallic layer over the substrate to cover the silicon nanocrystals and the tunneling dielectric layer;
performing a first rapid thermal annealing process so that the metallic layer reacts with the silicon nanocrystals to form the salicide nanocrystals; and
removing unreacted metallic layer.

3. The method of claim 2, further comprising a step of performing a second rapid thermal annealing process after the step of removing the unreacted metallic layer.

4. The method of claim 2, wherein the step of removing the metallic layer comprises performing an etching operation.

5. The method of claim 2, wherein the material constituting the metallic layer comprises a refractory metal.

6. The method of claim 5, wherein the refractory metal is selected from a group consisting of titanium, tungsten, platinum, cobalt and nickel.

7. The method of claim 1, wherein the step of forming the silicon nanocrystals comprises performing a chemical vapor deposition process.

8. The method of claim 1, wherein the material constituting the conductive layer comprises doped polysilicon.

9. A method for manufacturing a non-volatile memory, comprising the steps of:
providing a substrate, wherein the substrate comprises a memory cell region and a peripheral circuit region;
forming a tunneling dielectric layer on the substrate;
forming a plurality of silicon nanocrystals on the tunneling dielectric layer;
performing a silicide process such that the silicon nanocrystals are transformed into a plurality of salicide nanocrystals;
forming a dielectric layer over the substrate to cover the salicide nanocrystals and the tunneling dielectric layer;
removing the dielectric layer, the salicide nanocrystals and the tunneling dielectric layer in the peripheral circuit region;
forming a gate oxide layer over the dielectric layer in the memory cell region and the substrate in the peripheral circuit region;
forming a conductive layer over the gate oxide layer;
patterning the conductive layer, the gate oxide layer, the dielectric layer, the layer of salicide nanocrystals and the tunneling dielectric layer until the substrate surface is exposed so that a first gate structure is formed in the memory cell region and a second gate structure is formed in the peripheral circuit region; and
forming a first source/drain region in the substrate on the respective sides of the first gate structure and forming a second source/drain region in the substrate on the respective sides of the second gate.

10. The method of claim 9, wherein the suicide process comprises:
forming a metallic layer over the substrate to cover the silicon nanocrystals and the tunneling dielectric layer;
performing a first rapid thermal annealing process so that the metallic layer reacts with the silicon nanocrystals to form salicide nanocrystals; and
removing unreacted metallic layer.

11. The method of claim 10, further comprising a step of performing a second rapid thermal annealing process after the step of removing the unreacted metallic layer.

12. The method of claim 10, wherein the method of removing the unreacted metallic layer comprises performing an etching operation.

13. The method of claim 10, wherein the material constituting the metallic layer comprises a refractory metal.

14. The method of claim 13, wherein the refractory metal is selected from a group consisting of titanium, tungsten, platinum, cobalt and nickel.

15. The method of claim 9, wherein the step of forming the silicon nanocrystals comprises performing a chemical vapor deposition process.

16. The method of claim 9, wherein the step of forming the gate oxide layer comprises performing a thermal oxidation process.

17. The method of claim 9, wherein the step of removing the dielectric layer, the salicide nanocrystals and the tunneling dielectric layer in the peripheral circuit region comprises:
forming a patterned photoresist layer over the dielectric layer in the memory cell region; and
etching the dielectric layer, the salicide nanocrystals and the tunneling dielectric layer in the peripheral circuit region using the patterned photoresist layer as a mask.

18. The method of claim 9, wherein the material constituting the dielectric layer comprises silicon nitride.

19. The method of claim 9, wherein the material constituting the conductive layer comprises doped polysilicon.
